(19) United States
(12) Patent Application Publication
(10) Pub. No.: US 2010/0219487 A1
(43) Pub. Date: Sep. 2, 2010

(54) METHOD FOR MANUFACTURING A SENSOR COMPONENT AND SENSOR COMPONENT

(76) Inventor: Dieter Donis, Stuttgart (DE)

Correspondence Address: KENYON & KENYON LLP, ONE BROADWAY, NEW YORK, NY, 10004, US

(21) Appl. No.: 12/305,746

(22) PCT Filed: Sep. 6, 2007
(86) PCT No.: PCT/EP07/59316

§ 371 Date: Apr. 12, 2010

(30) Foreign Application Priority Data
Oct. 6, 2006 (DE) 10 2006 047 395.7

(51) Int. Cl. H01L 29/66; B32B 37/06

(52) U.S. Cl. 257/414; 156/89.16; 257/E29.166

(57) ABSTRACT

A method for manufacturing a sensor component and a sensor component. The sensor component has a semiconductor substrate and a metal substrate. The semiconductor substrate and the metal substrate are bonded together with the aid of a low-temperature process. A bonding material containing metal particles is applied in a first step to the semiconductor substrate and/or the metal substrate and a sintering process is used in a second step for producing the bond between the semiconductor substrate and the metal substrate.

### BACKGROUND INFORMATION

A method for manufacturing deformation sensors having a strain gauge and for manufacturing strain gauges and deformation sensors is known from published German patent document DE 101 56 406. The method has the disadvantage that, for joining the strain gauges with the rest of the sensor component, low melting glass (seal glass) is applied to at least one surface to be bonded and the joined system is heated. On the one hand, it is necessary here to provide a comparatively high process temperature of, for example, approximately 440° C. or higher and, on the other hand, there is frequently the problem that inclusions (so called shrink cavities) are embedded in the seal glass layer which have a detrimental effect on the bond of the strain gauge with the rest of the sensor component. Furthermore, the comparatively high process temperature may cause comparatively high mechanical stresses during manufacture of the bond which may result in the strain gauge failing (for example, due to failure of the analyzing electronics) or becoming detached from the rest of the sensor component.

### SUMMARY

A method according to the present invention for manufacturing a sensor component and the sensor component according to the present invention are advantageous in that, by using a low-temperature step for producing the bond between a semiconductor substrate and a metal substrate, the disadvantages of the related art are avoided or at least reduced. In particular, no or fewer shrink cavities or inclusions are present in a bonding material and no or fewer thermomechanical stresses are present in a bonding layer. It is possible according to the present invention that occurrences of failures are avoided or reduced and, moreover, that an improved as well as simplified and, thus, more cost-effective manufacturing flow is achieved. According to the present invention, higher stress reversal strength, and, moreover, great strength of the bond—even at comparatively high temperatures of more than 250° C.—may also be achieved.

According to the present invention, it may be preferable that that prior to a first step, a metal plating layer is applied to the semiconductor substrate and/or to the metal substrate. This makes it possible to improve the bond of the metal substrate with the semiconductor substrate in an advantageous manner. In particular, bonding characteristics of the bonding material with the respective adjacent substrate material may be improved.

Furthermore, it may be preferable that, prior to a second step, the bonding material is provided as a powdery or paste-like material or that the bonding material has metal particles and, furthermore, additives, in particular ground waxes, and that the additives constitute a comparatively small proportion of the bonding material. This makes it possible that the bonding material may be created to be particularly well processable so that the manufacturing process according to the present invention may be devised to be particularly cost-effective, simple, and comparatively straightforward.

Furthermore, it may be preferable that the metal particles are nanoparticles, in particular ranging from being smaller than approximately 1,000 nanometers and smaller than approximately 500 nanometers, to smaller than approximately 100 nanometers.

A particularly large surface is formed thereby with which the metal particles may sinter together or sinter onto each other so that a particularly good strength within the bonding material is ensured.

According to the present invention it may also be preferable that, during the second step, the metal substrate and the semiconductor substrate are pressed together with the aid of a force which substantially exceeds the semiconductor substrate's own weight or, alternatively, are pressed together using a force which is essentially formed only by the metal substrate's or the semiconductor substrate's own weight, thereby producing optimal bonding of the substrates depending on the intended process sequence or depending on the bonding material used.

A further object of the present invention is a sensor component having a semiconductor substrate and a metal substrate, the semiconductor substrate and the metal substrate being bonded together with the aid of a low-temperature process and a bonding material having metal particles being provided for bonding the semiconductor substrate with the metal substrate, thereby, according to the present invention, achieving a good bond of the semiconductor substrate with the metal substrate via a sintered structure of the bonding material.

According to the present invention it may be preferable that a function layer is provided between the semiconductor substrate and the bonding material and/or between the metal substrate and the bonding material, the function layer being provided in particular as a function layer producing an electrical insulation or conductance and/or producing a thermal insulation and/or producing an enhanced layer adhesion. In the sensor component according to the present invention, it is thereby possible that additional functionalities are implemented with the aid of the design according to the present invention.

Exemplary embodiments of the present invention are depicted in the drawings and explained in greater detail in the following description.

### BRIEF DESCRIPTION OF THE DRAWINGS

FIGS. 1a, 1b and 2 to 7 show schematic illustrations of a first specific embodiment of a sensor component and a method for manufacturing the sensor component according to the present invention.

FIG. 8 shows a second specific embodiment of a sensor component according to the present invention.

### DETAILED DESCRIPTION OF EXAMPLE EMBODIMENTS

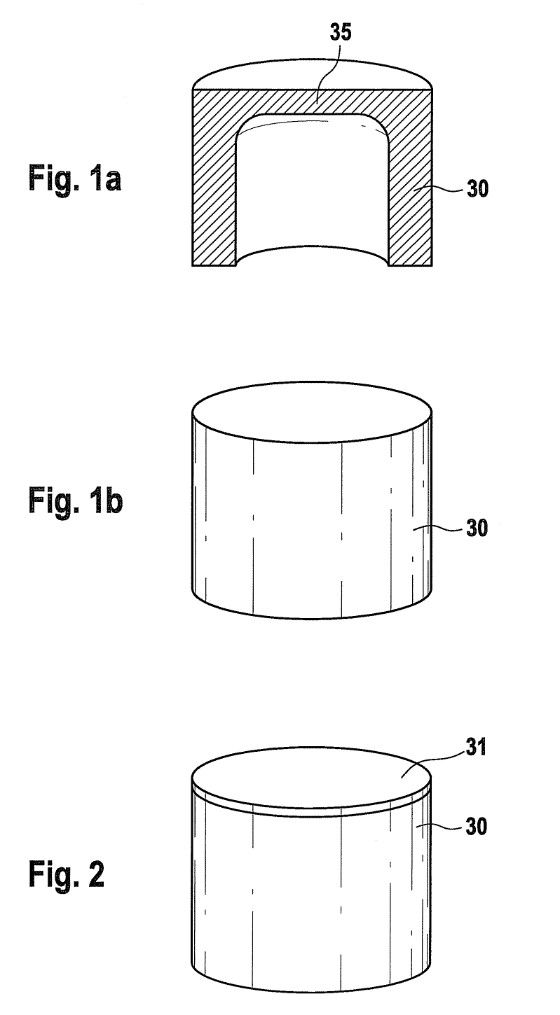

FIGS. 1a and 1b respectively show a schematic sectional view and a perspective view of a metal substrate 30. Metal substrate 30 has an essentially cylindrical shape. The cylinder, starting from a front face, has a recess along its longitudinal axis and the other front face is closed and forms a sensor diaphragm 35, e.g., for forming a pressure sensor. It may be provided that sensor diaphragms 35 of different thicknesses are used for sensing different pressure ranges. A pressure state present in the interior of the cylinder, i.e., in the recess, exerts a pressure force on the front face of metal substrate 30, thereby curving sensor diaphragm 35. A semiconductor substrate 20 (not shown in FIG. 1), bonded with metal substrate 30 on the sensor diaphragm 35, is able to detect a curvature of sensor diaphragm 35. For this purpose, a bond between semiconductor substrate 20 and metal substrate 30 via a bonding material 40 (not shown in FIG. 1) is produced in a low temperature process with the aid of a sintering process.

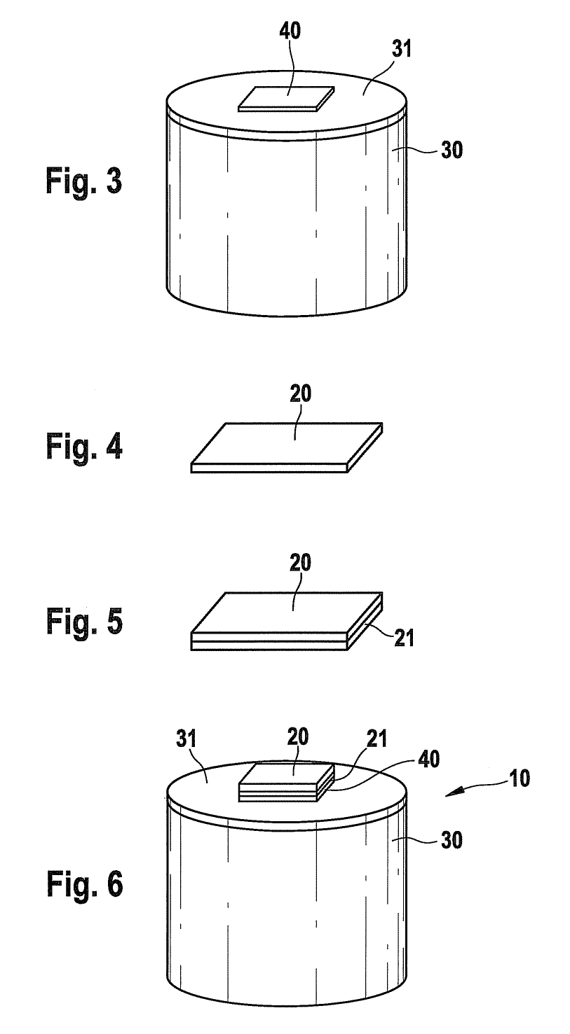

The steps required for this are depicted in FIGS. 2 through 6. FIG. 2 shows the state after the application of a second metal plating layer 31 on metal substrate 30. FIG. 3 shows the state after the application of a bonding material 40 onto second metal plating layer 31. Bonding material 40 may be applied via screen printing, via stencil printing, via spraying and/or via dispensing, for example. Second metal plating layer 31 is used in particular for a better bond between bonding material 40 and metal substrate 30. FIG. 4 shows a semiconductor substrate 20 (in an enlarged depiction relative to FIGS. 1 through 3). FIG. 5 shows the state after the application of a first metal plating layer 21 to semiconductor substrate 20. In this case, first metal plating layer 21 is used in particular for a better bond between bonding material 40 and semiconductor substrate 20. According to the present invention, metal plating layers 21, 31 may, in particular, be gold layers and/or silver layers or layers composed of alloys of these metals or of these metals and other noble metals.

FIG. 6 shows a sensor component 10 manufactured according to the method according to the present invention and thus the state after the application of semiconductor substrate 20 (including first metal plating layer 21) to bonding material 40 already situated on metal substrate 30. Semiconductor substrate 20 is applied in the area of sensor diaphragm 35. In particular, bonding material 40 is merely applied or provided in the area of subsequent semiconductor substrate 20. According to the present invention, metal plating layers 21, 31 are applied over the entire extent of the surfaces, facing each other, of the respective substrates 20, 30, but they may, however, be alternatively (not shown) applied or provided merely in the area of subsequent semiconductor substrate 20.

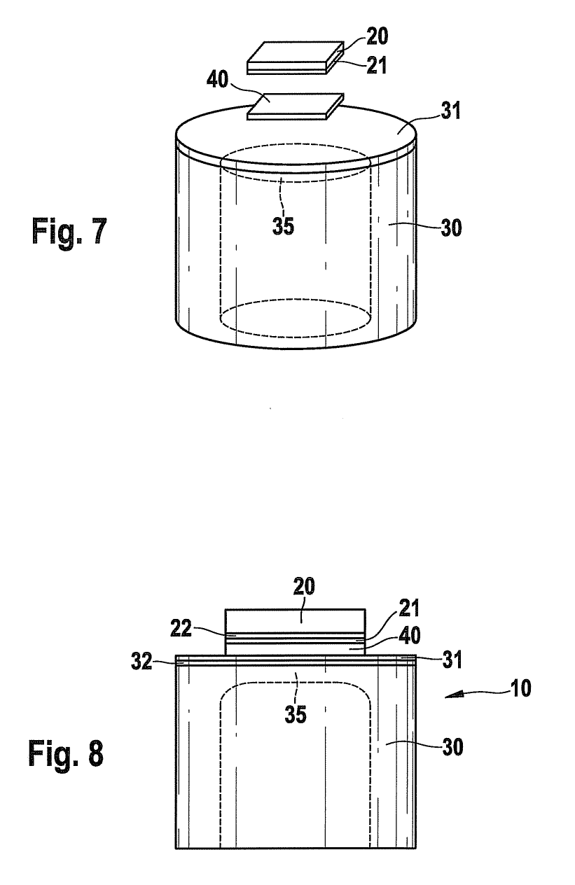

In a schematic exploded view, FIG. 7 again shows the construction of the bond between semiconductor substrate 20 and metal substrate 30 in sensor component 10 according to the present invention, this being merely the structure or layer sequence in principle in the bonding area. First metal plating layer 21, second metal plating layer 31, and bonding material 40 are situated between metal substrate 30 or sensor diaphragm and semiconductor substrate 20.

According to the present invention, bonding material 40 includes metal particles (not shown), in the form of so-called nanoparticles and, in particular, in the form of silver particles or of particles of a silver alloy. Bonding material has a powdery or a paste-like consistency. The metal particles or nanoparticles have a size of under approximately 1,000 nanometers, preferably in a range of approximately 10 nanometers to approximately 100 nanometers or in a range of approximately 100 nanometers to approximately 600 nanometers, this being the median particle size at a given particle size distribution. In addition to the metal particles, bonding material 40 also has organic additives which preferably enclose the metal particles at least partially and are responsible for the powdery or paste-like consistency of bonding material 40. According to the present invention, it is thereby possible to work with low temperatures during the bonding process and that an adequate bond, which is stable over long service lives, between substrates 20, 30 is still manufacturable.

According to the present invention, it may be provided that either a contact pressure or a contact force is exerted between substrates 20, 30 during the bonding process step or, alternatively, it may be provided that virtually no contact force is exerted (except for the weight of the substrate resting on top, for example, semiconductor substrate 20).

According to the present invention, combinations of temperatures and contact pressures/contact forces of, for example, approximately 250° C. and approximately 10 megapascal to approximately 100 megapascal, preferably of approximately 15 megapascal to approximately 45 megapascal are provided, or also of 300° C. and approximately 10 megapascal to no contact pressure at all. In contrast to processes which require a higher temperature, it is advantageously possible according to the present invention that the time duration of the oven process and thus the cycle times during the manufacture of sensor component 10 may be reduced. Moreover, it is possible to use smaller ovens which further reduce the manufacturing costs of sensor component 10. The operation of sensor component 10 manufactured according to the present invention results in the advantage that bonding material 40 may be manufactured largely free of shrink cavities, that reduced thermomechanical stresses are possible, thereby achieving a lower rate of chip failures, that there is increased stress reversal strength, and that there is greater strength of the bond, even at comparatively high temperatures of over 250° C., for example.

FIG. 8 schematically shows a second specific embodiment of sensor component 10. The second specific embodiment differs from the first specific embodiment by the fact that a first function layer 22 is situated between first metal plating layer 21 and semiconductor substrate 20. Alternatively or additionally, a second function layer 32 may be situated between second metal plating layer 31 and metal substrate 30. According to the present invention, it is possible that sensor component 10 has further advantageous characteristics due to the function layers 22, 32, e.g., greater electrical strength (i.e., better electrical insulation), an enhanced layer bond, and a thermal insulation of the bonding area from semiconductor substrate 20 and/or metal substrate 30. Function layers 22, 32 may be silica layers, or also nitride layers or the like, for example. Function layers 22, 32 may be applied with the aid of a common deposition method, for example.

1-10. (canceled)

11. A method for manufacturing a sensor component having a semiconductor substrate and a metal substrate, comprising:
bonding the semiconductor substrate and the metal substrate to one another with the aid of a low-temperature process;
applying a bonding material to at least one of the semiconductor substrate and the metal substrate in a first step; and
using a sintering process in a second step to produce the bond between the semiconductor substrate and the metal substrate.

12. The method as recited in claim 11, further comprising:
prior to the first step, applying a metal plating layer to one of the semiconductor substrate and the metal substrate.

13. The method as recited in claim 11, further comprising:
prior to the second step, providing the bonding material as one of a powdery material and a paste-like material having metal particles.

14. The method as recited in claim 13, wherein the bonding material includes organic additives in addition to the metal particles.

15. The method as recited in claim 13, wherein the metal particles are nanoparticles smaller than approximately 1 micrometer.

16. The method as recited in claim 13, wherein the metal particles are nanoparticles smaller than approximately 500 nanometers.

17. The method as recited in claim 14, wherein the additives constitute a comparatively small proportion of the bonding material.

18. The method as recited in claim 11, further comprising:
during the second step, pressing the metal substrate and the semiconductor substrate together using a force which substantially exceeds the semiconductor substrate's own weight.

19. The method as recited in claim 11, further comprising:
during the second step, pressing the metal substrate and the semiconductor substrate together using only the weight of one of the metal substrate and the semiconductor substrate.

20. A sensor component, comprising:
a semiconductor substrate;
a metal substrate joined to the semiconductor substrate via a low-temperature process; and
a bonding material having metal particles which facilitate bonding of the semiconductor substrate with the metal substrate.

21. The sensor component as recited in claim 20, further comprising:
a function layer between the bonding material and one of the semiconductor substrate and the metal substrate, the function layer providing one of an electrical insulation, a conductance, a thermal insulation and an enhanced layer adhesion.
